(19) United States
(12) Patent Application Publication
(10) Pub. No.: US 2024/0405132 A1
(43) Pub. Date: Dec. 5, 2024

(54) DIELECTRIC BARRIER FOR REFLECTIVE BACKPLANE OF TUNABLE OPTICAL METASURFACES

(71) Applicant: Lumotive, Inc., Redmond, WA (US)

(72) Inventors: Erik Edward Josberger, Renton, WA (US); Linda Gail Conway, Duvall, WA (US); Gleb M. Akselrod, Kenmore, WA (US)

(21) Appl. No.: 18/327,777

(22) Filed: Jun. 1, 2023

(51) Int. Cl. H01L 31/0216; G02B 1/00; H01L 31/0203; H01L 31/0232; H01L 31/0264; H01L 31/065; H01L 31/18

(52) U.S. Cl. CPC H01L 31/02165; G02B 1/002; H01L 31/0203; H01L 31/02327; H01L 31/0264; H01L 31/065; H01L 31/1892

(57) ABSTRACT

In one embodiment described herein, a device includes optically reflective metal patches positioned within a dielectric substrate. A dielectric barrier layer separates the reflective metal patches and the dielectric substrate to prevent diffusion of the reflective metal into the dielectric substrate. An optically transparent dielectric spacer layer is deposited thereon, and an array of metal elements extend from the dielectric spacer layer. A dielectric coating is applied to the top wall and sidewalls of each metal element. A conductive barrier material is positioned between the base wall of each metal element and the dielectric spacer layer. A tunable dielectric material is positioned within the gaps between adjacent metal elements.

### TECHNICAL FIELD

This disclosure relates to optical metasurfaces, reflectors, deflectors, and antenna elements, including tunable optical metasurfaces.

### BRIEF DESCRIPTION OF THE DRAWINGS

FIG. 1A shows a top overview of a metallic holographic metasurface device in accordance with the embodiments of the disclosure.

FIG. 1B is a cross-sectional view of a one-dimensional metallic holographic metasurface device in accordance with embodiments of the disclosure.

FIG. 2 shows a cross-sectional view of one subwavelength holographic element, including a pair of copper pillars and a full backplane structure in the array of FIG. 1B, in accordance with embodiments of the disclosure.

FIG. 3A shows a cross-sectional view of one subwavelength holographic element, including a pair of copper pillars and a partial backplane structure, in accordance with the embodiments of the disclosure.

FIGS. 3B and 3C show cross-sectional views of one subwavelength holographic element, including a pair of copper pillars and a partial backplane structure with dielectric barrier layers, in accordance with embodiments of the disclosure.

FIG. 4A shows a cross-sectional view of the deposition of a plurality of dielectric layers over a wafer substrate in accordance with embodiments of the disclosure.

FIG. 4B shows a cross-sectional view of etching the top dielectric layer to form trenches in accordance with the embodiments of the disclosure.

FIG. 4C shows a cross-sectional view of depositing a dielectric barrier layer within the trenches in accordance with the embodiments of the disclosure.

FIG. 4D shows a copper seed layer deposited within the trenches in accordance with embodiments of the disclosure.

FIG. 4E illustrates copper deposited to fill each of the trenches in accordance with embodiments of the disclosure.

FIG. 4F shows a cross-sectional view of the chemical mechanical planarization (CMP) of the copper layer to expose the top dielectric layer in accordance with the embodiments of the disclosure.

FIG. 5 shows a cross-sectional view of depositing dielectric layers over the copper layer and the top dielectric layer in accordance with embodiments of the disclosure.

FIG. 6A shows a cross-sectional view of patterning the copper layer over the dielectric layer using a damascene process in accordance with embodiments of the disclosure.

FIG. 6B shows a cross-sectional view of chemically etching the top dielectric layer to form nano-gaps between copper pillars in accordance with embodiments of the disclosure.

FIG. 6C shows a cross-sectional view of applying a dielectric coating to the copper pillars in accordance with the embodiments of the disclosure.

FIG. 6D shows a cross-sectional view of an electrically tunable material disposed over the copper pillars and filling the nano-gaps between copper pillars in accordance with embodiments of the disclosure.

FIG. 7 shows a cross-sectional view of a metasurface with patterned copper elements and copper patches, according to various embodiments of the disclosure.

### DETAILED DESCRIPTION

This disclosure may be understood by reference to the following detailed description, taken in conjunction with the drawings as described below. It is noted that, for purposes of illustrative clarity, certain elements in various drawings may not be drawn to scale, and other elements may be omitted to avoid obscuring the focus of this application.

Additional descriptions, variations, functionalities, and usages for optical metasurfaces are described in U.S. Pat. No. 10,451,800 granted on Oct. 22, 2019, entitled “Plasmonic Surface-Scattering Elements and Metasurfaces for Optical Beam Steering;” U.S. Pat. No. 10,665,953 granted on May 26, 2020, entitled “Tunable Liquid Crystal Metasurfaces;” and U.S. Pat. No. 11,092,675 granted on Aug. 17, 2021, entitled “Lidar Systems based on Tunable Optical Metasurfaces,” each of which is hereby incorporated by reference in its entirety. Many of the metasurfaces described in the above-identified U.S. patents include one-dimensional arrays of parallel rails, two-dimensional arrays of elongated rails, and/or two-dimensional arrays of pillars positioned above a planar reflective surface, reflective layers, or optically transmissive surfaces.

This disclosure includes various embodiments and variations of tunable optical metasurface devices and methods for manufacturing the same. It is appreciated that the metasurface technologies described herein may incorporate or otherwise leverage prior advancements in surface scattering antennas, such as those described in U.S. Patent Publication No. 2012/0194399, published on Aug. 2, 2012, entitled “Surface Scattering Antennas;” U.S. Patent Publication No. 2019/0285798 published on Sep. 19, 2019, entitled “Plasmonic Surface-Scattering Elements and Metasurfaces for Optical Beam Steering;” and U.S. Patent Publication No. 2018/0241131 published on Aug. 23, 2018, entitled “Optical Surface-Scattering Elements and Metasurfaces;” each of which is hereby incorporated by reference in its entirety. Additional elements, applications, and features of surface scattering antennas are described in U.S. Patent Publication No. 2014/0266946, published Sep. 18, 2014, entitled “Surface Scattering Antenna Improvements;” U.S. Patent Publication No. 2015/0318618, published Nov. 5, 2015, entitled “Surface Scattering Antennas with Lumped Elements;” U.S. Patent Publication No. 2015/0318620 published Nov. 5, 2015, entitled “Curved Surface Scattering Antennas;” U.S. Patent Publication No. 2015/0380828 published on Dec. 31, 2015, entitled “Slotted Surface Scattering Antennas;” U.S. Patent Publication No. 2015/0162658 published Jun. 11, 2015, entitled “Surface Scattering Reflector Antenna;” U.S. Patent Publication No. 2015/0372389 published Dec. 24, 2015, entitled “Modulation Patterns for Surface Scattering Antennas;” PCT Application No. PCT/US18/19269 filed on Feb. 22, 2018, entitled “Control Circuitry and Fabrication Techniques for Optical Metasurfaces,” U.S. Patent Publication No. 2019/0301025 published on Oct. 3, 2019, entitled “Fabrication of Metallic Optical Metasurfaces;” U.S. Publication No. 2018/0248267 published on Aug. 30, 2018, entitled “Optical Beam-Steering Devices and Methods Utilizing Surface Scattering Metasurfaces;” and U.S. patent application Ser. No. 17/685,621 filed on Mar. 3, 2022, entitled “Liquid Crystal Metasurfaces with Cross-Backplane Optical Reflectors,” each of which is hereby incorporated by reference in its entirety.

In various embodiments, the elongated metal rails or pillars have subwavelength dimensions suitable for operation within a specific bandwidth of optical frequencies (e.g., a bandwidth of infrared optical frequencies). The width of each elongated metal rail or pillar may be, for example, less than the smallest wavelength of the operational bandwidth. Similarly, each elongated metal rail may extend from the dielectric substrate to a height less than the smallest wavelength of the operational bandwidth. Specific descriptions of optical resonant antenna configurations, feature sizes, and manufacturing techniques are described in the patents and patent publications incorporated by reference herein. each

Tunable optical metasurfaces may be used for beamforming, including three-dimensional beam shaping, two-dimensional beam steering, and/or one-dimensional beam steering. The presently described systems and methods can be applied to tunable metasurfaces utilizing various architectures and designs to deflect optical radiation within an operational bandwidth. In various embodiments, a controller or metasurface driver selectively applies a pattern of voltages to an array of optical structures. Voltage differentials across adjacent optical structures modify the refractive indices of dielectric material therebetween. A combination of phase delays created by the pattern of applied voltages creates constructive interference in the desired beam steering direction.

Various examples of tunable optical metasurfaces are described herein and depicted in the figures. For example, a tunable optical metasurface includes an array of metal elements (e.g., antenna elements, resonator elements, elongated resonator rails, arrays of metal pillars, pairs of resonator pillars, etc.). For instance, in some embodiments, the array of metal elements comprises a one-dimensional array of elongated metal resonator rails arranged parallel to one another with respect to an optical reflector, such as an optically reflective layer of metal or a Bragg reflector. Liquid crystal, or another refractive index tunable dielectric material, is positioned in the gaps or channels between adjacent resonator rails (e.g., adjacent elongated metal rails). Liquid crystal is used in many of the examples provided in this disclosure. However, it is appreciated that alternative dielectric materials with tunable refractive indices and/or combinations of different dielectric materials with tunable refractive indices may be utilized instead of liquid crystal in many instances. Examples of suitable tunable dielectric materials that have tunable refractive indices include liquid crystals, electro-optic polymer, chalcogenide glasses, and/or various semiconductor materials.

In various embodiments, biasing the liquid crystal in a metasurface with a pattern of voltage biases changes the reflection phase of the optical radiation. For example, each different voltage pattern applied across the metasurface corresponds to a different reflection phase pattern. Each different reflection phase pattern of a one-dimensional array of optical structures (e.g., elongated metal resonator rails) corresponds to a different steering angle in a single dimension. A digital or analog controller (controlling current and/or voltage), such as a metasurface driver, may apply a differential voltage bias pattern to achieve a target beam shaping, such as a target beam steering angle. The term “beam shaping” is used herein in a broad sense to encompass one-dimensional beam steering, two-dimensional beam steering, wavelength filtering, beam divergence, beam convergence, beam focusing, and/or controlled deflection, refraction, and/or reflection of incident optical radiation.

Various examples and metal elements, such as elongated metal rails and metal pillars, are illustrated and described in many instances as being copper or as including copper (e.g., a copper alloy). Copper antenna elements may, for example, be fabricated using modified or variations of damascene processes for semiconductor devices. However, it is appreciated that other metals may also be utilized, including but not limited to tungsten, aluminum, copper alloys, and/or combinations thereof.

In various examples, a conductive barrier material is positioned between the base wall of the metal core of each metal element and the underlying dielectric substrate. The conductive barrier material may be, for example, tantalum (Ta), tantalum nitride (TaN), titanium nitride (TiN), and/or a combination thereof.

A tunable dielectric material that has a tunable refractive index (e.g., liquid crystal, as described above) is positioned within the channels, gaps, or nano-gaps between adjacent metal elements. As described above, the tunable dielectric material deposited within the gaps between adjacent metal elements may include liquid crystal, an electro-optic polymer, a chalcogenide glass, and/or a tunable semiconductor material.

The passivation coating or dielectric barrier coating may be deposited on the tunable optical device as a single or uniform layer that covers the sidewalls and top wall of each metal antenna element and the base or lower surface of each gap. The passivation or dielectric barrier coating may be, for example, a thin silicon nitride (SiN) layer to passivate the metal antenna elements. The passivation coating or dielectric barrier coating may be optically transparent for wavelengths within the operational bandwidth of the metasurface. The dielectric barrier coating applied to the metal antenna elements may be, for example, silicon carbide nitride, silicon carbide, aluminum oxide (AlOₓ), hafnium oxide (HfO₂, silicon oxide (SiO₂), aluminum nitride (AlN), boron nitride (BN), and/or another passivating dielectric material.

The various tunable metasurface devices described herein can be manufactured using various semiconductor manufacturing processes including, but not limited to, damascene processes, deposition processes, etching processes, lithography processes, patterning processes, chemical mechanical planarization processes, and the like. One example manufacturing process includes etching a dielectric layer to form trenches in the dielectric layer (e.g., a one-dimensional or two-dimensional array of trenches). Each trench may have substantially vertical sidewalls separated by a base wall that has a width less than a wavelength in an operational bandwidth of the tunable metasurface. A conductive barrier material may be deposited to cover at least the base wall of each trench. The conductive barrier material may be used for electrical control line routing to apply voltage patterns to the metal antenna elements.

Some of the embodiments described and illustrated herein are described in the context of one-dimensional arrays of elongated metal rails. In some such embodiments, the width of each elongated metal rail may be subwavelength (e.g., 100-500 nanometers, depending on the operational bandwidth), while the length of each elongated metal rail may be on the order of tens or hundreds of microns, centimeters, or even tens of centimeters. However, it is also appreciated that two-dimensional arrays of elongated metal rails may be utilized. In some embodiments, the length of each elongated metal rail, according to any of the embodiments described herein, may also have subwavelength dimensions.

A two-dimensionally steerable tunable optical device may include a two-dimensional array of metal antenna elements (e.g., circular pillars, rectangular pillars, square pillars, elongated rectangular pillars, etc.) extending from a dielectric substrate (e.g., the dielectric spacer layer as described below). The metal antenna elements may be spaced from one another by less than a wavelength of an operational bandwidth to form subwavelength gaps between adjacent or neighboring metal antenna elements.

In various examples, a method for fabricating an optical metasurface includes forming a reflective backplane structure that includes a lower copper layer within a dielectric substrate. The reflective back plane includes a lower dielectric barrier layer that separates the lower copper layer from the dielectric substrate to prevent copper diffusion and/or corrosion. An optically transparent spacer layer (e.g., one or more optically transparent dielectric layers, such as low-k dielectric layer(s)) is formed over the reflective backplane structure, followed by an upper copper layer with an upper barrier layer. In various embodiments, a damascene process or variation thereof may be used.

As described herein, the upper copper layer may include a plurality of nano-gaps vertically extending between metal elements, such as rails, pillars, or the like. The nano-gaps may be filled with a dielectric fill material. The upper barrier layer may be positioned between the upper copper layer and the upper spacer layer and also between the upper copper layer and the dielectric fill material. The upper barrier layer may be dielectric or conductive. Examples of a conductive upper barrier layer include tantalum (Ta), tantalum nitride (TaN), and titanium nitride (TiN).

The dielectric fill material in the nano-gaps is removed, along with a portion of the upper barrier layer, to expose the portions in the nano-gaps of the upper copper layer. A dielectric coating layer is applied over the top portion and exposed side portions of the upper copper layer to form a protected upper copper layer. The nano-gaps are then filled with an electrically tunable dielectric material, such as liquid crystal.

In some examples, the lower dielectric barrier layer and/or the dielectric coating layer includes one or more of SiN, SiC, SiCN, AL2O3, HfO2, and SiO2. In some examples, an optically reflective metal coating layer, such as silver, may be applied over the dielectric coating layer on the elements of the upper copper layer prior to filling the nano-gaps with the electrically tunable dielectric material. The upper copper layer may thereby be formed as a plurality of copper pillars vertically extending from the dielectric spacer layer (e.g., a one-dimensional or two-dimensional array of copper pillars). In another embodiment, the upper copper layer may thereby be formed as a one-dimensional array of elongated copper rails.

The lower copper layer provides an optically reflective surface and may, in some embodiments, be formed as copper patches. The copper patches may be strategically positioned under the nano-gaps between adjacent copper pillars or copper rails of the upper copper layer. For example, each copper patch may have a width corresponding to the pitch of the adjacent copper pillars of the upper copper layer.

A tunable optical metasurface may be formed using any combination of the various methods and method steps described herein. An example tunable optical metasurface may include an optically reflective metallic layer beneath an array of metal elements (e.g., pillars or rails) spaced to form subwavelength gaps therebetween that are filled with a tunable dielectric material. The optically reflective metallic layer may include, for example, reflective metal patches (e.g., copper patches) positioned within trenches in a dielectric substrate. A dielectric barrier layer may be positioned between the reflective metal patches and the dielectric substrate. The dielectric barrier layer is optically transparent and prevents diffusion of the reflective metal into the dielectric substrate.

An optically transparent dielectric spacer layer may be deposited on the optically reflective metallic layer to separate it from the array of metal pillars or rails. The array of metal pillars or rails extends from the dielectric spacer layer, where the individual pillars or rails are spaced from one another by less than a wavelength of an operational bandwidth to form subwavelength gaps between adjacent metal elements. A dielectric coating is applied to the top wall and sidewalls of each metal element (e.g., as a passivation coating). A conductive barrier material is positioned between the base wall of each metal element and the dielectric spacer layer. A tunable dielectric material is positioned within the gaps between adjacent metal elements. A glass, polymer, transparent dielectric, and/or sapphire cover may be used to encapsulate and maintain the tunable dielectric material within the gaps.

The width of each metal element may be less than the smallest wavelength of the operational bandwidth. The height to which each metal element extends from the dielectric spacer layer may also be less than the smallest wavelength of the operational bandwidth. In embodiments in which the array of metal elements includes a two-dimensional array of metal antenna resonator elements, the length, width, and height of each metal element may be subwavelength.

Examples of metasurfaces are described herein that can be used for transmitting or receiving. Systems incorporating the metasurfaces described herein may be operated as only a transmitter, as only a receiver, simultaneously as a transmitter and receiver, as a time-multiplexed transmitter/receiver, as a frequency-multiplexed transmitter/receiver, with the first metasurface acting as a transmitter and a second metasurface acting as a receiver, or in another transmit/receive configuration or operation technique. Additionally, the metasurfaces described herein may be used to control, tune, or modify reflection phase patterns. For example, one or more metasurfaces may be used to control (i) the reflection phase, (ii) the reflection amplitude, or (iii) the reflection phase and the reflection/transmission amplitude of a signal. Accordingly, a metasurface may be utilized in any of the embodiments described herein to control the complex phase and/or complex amplitude of reflected optical radiation.

Any of the variously described embodiments herein may be manufactured with dimensions suitable for optical bandwidths for optical sensing systems such as LiDAR, optical communications systems, optical computing systems, and displays. For example, the systems and methods described herein can be configured with metasurfaces that operate in the sub-infrared, mid-infrared, high-infrared, and/or visible-frequency ranges (generally referred to herein as “optical”). Given the feature sizes needed for sub-wavelength optical antennas and antenna spacings, the described metasurfaces may be manufactured using micro-lithographic and/or nano-lithographic processes, such as fabrication methods commonly used to manufacture complementary metal-oxide-semiconductor (CMOS) integrated circuits.

Some of the infrastructure that can be used with embodiments disclosed herein is already available, such as general-purpose computers, computer programming tools and techniques, digital storage media, and communication links. Many of the systems, subsystems, modules, components, and the like that are described herein may be implemented as hardware, firmware, and/or software. Various systems, subsystems, modules, and components are described in terms of the function(s) they perform because such a wide variety of possible implementations exist. For example, it is appreciated that many existing programming languages, hardware devices, frequency bands, circuits, software platforms, networking infrastructures, and/or data stores may be utilized alone or in combination to implement a specific control function.

It is also appreciated that two or more of the elements, devices, systems, subsystems, components, modules, etc. that are described herein may be combined as a single element, device, system, subsystem, module, or component. Moreover, many of the elements, devices, systems, subsystems, components, and modules may be duplicated or further divided into discrete elements, devices, systems, subsystems, components, or modules to perform subtasks of those described herein. Any aspect of any embodiment described herein may be combined with any other aspect of any other embodiment described herein or in the other disclosures incorporated by reference, including all permutations and combinations thereof, consistent with the understanding of one of skill in the art reading this disclosure in the context of such other disclosures.

To the extent used herein, a computing device, system, subsystem, module, driver, or controller may include a processor, such as a microprocessor, a microcontroller, logic circuitry, or the like. A processor may include one or more special-purpose processing devices, such as application-specific integrated circuits (ASICs), programmable array logic (PAL), programmable logic array (PLA), a programmable logic device (PLD), field-programmable gate array (FPGA), or another customizable and/or programmable device. The computing device may also include a machine-readable storage device, such as non-volatile memory, static RAM, dynamic RAM, ROM, magnetic memory, optical memory, flash memory, or another transitory or non-transitory machine-readable storage media. Various aspects of some embodiments may be implemented or enhanced using hardware, software, firmware, or a combination thereof.

The components of some of the disclosed embodiments are described and illustrated in the figures herein to provide specific examples. Many portions thereof could be arranged and designed in a wide variety of different configurations. Furthermore, the features, structures, and operations associated with one embodiment may be applied to or combined with the features, structures, or operations described in conjunction with another embodiment. In many instances, well-known structures, materials, or operations are not shown or described in detail to avoid obscuring aspects of this disclosure. The right to add any described embodiment or feature to any one of the figures and/or as a new figure is explicitly reserved.

The embodiments of the systems and methods provided within this disclosure are not intended to limit the scope of the disclosure but are merely representative of possible embodiments. In addition, the steps of a method do not necessarily need to be executed in any specific order, or even sequentially, nor do the steps need to be executed only once, except as explicitly stated or as contextually understood by one of skill in the art.

The disclosure provides methods for fabricating a metallic holographic metasurface device, which is operable at higher frequencies, especially at infrared or visible frequencies. When operating frequencies are scaled up to optical (infrared/visible) frequencies, the sizes of individual scattering elements and the spacing between adjacent scattering elements are proportionally down the scaled to preserve subwavelength/metamaterial aspect of the technology. The relevant length scales for operation at optical frequencies are typically on the order of microns or nanometers, which are smaller than the typical length scales for conventional printed circuit board (PCB) processes.

The metallic holographic metasurface device includes an array of hologram elements, which can be a one-dimensional array or a two-dimensional array. Each hologram element may include a pair or pairs of metal pillars, an electrically tunable material, and a backplane structure as a reflector.

The use of (metal elements (e.g., metal pillars or metal rails) reduces the coupling between the hologram elements of the metallic holographic metasurfaces. The metal elements do not allow the optical field to be penetrated from the electrically tunable material, such that the optical field is substantially confined within the electrically tunable material. As a result, the metal pillars isolate the hologram elements from each other in the array and reduce the optical coupling between the hologram elements.

The metal elements may include copper, gold, silver, aluminum, and the like. The present disclosure is directed to a damascene process for the fabrication of copper holographic metasurfaces, which include an array of copper pillars with electrically-tunable material filled in the nano-scale gaps between the copper pillars.

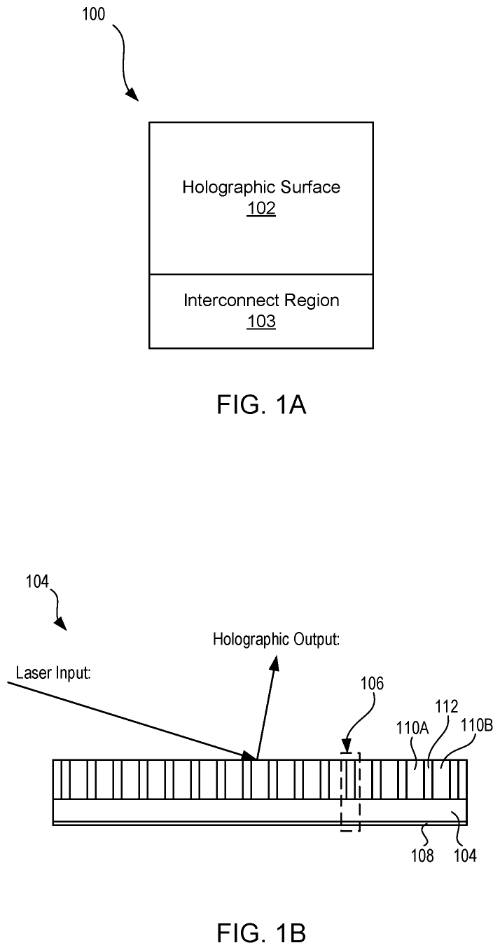

FIG. 1A shows a top overview of a metallic holo-graphic metasurface device in accordance with embodiments of the disclosure. A metallic holographic metasurface device 100 has a metallic holographic metasurface region 102, including an array of holographic elements on a first portion of a base 108, which can be seen in FIG. 1B. The metallic holographic metasurface region 102 includes an array of hologram elements. Each holographic element includes a pair or pairs of metal pillars and a refractive index tunable core material (e.g., a dielectric material with an electrically tunable refractive index) between the pair of metal pillars.

The holographic metasurface device 100 may also have an interconnect region 103 with CMOS transistors on a second portion of the chip. The CMOS transistors in the interconnect region 103 can control the voltage applied to the metal pillars of each of the holographic elements. The CMOS transistors have low static power consumption and high noise immunity. The array of holographic elements and the electrical control circuit are decoupled. In some embodiments, the interconnect region 103 may include a complex routing of wires with no active elements.

In some embodiments, the interconnect region may be at least partially mixed within the holographic metasurface (not shown). For instance, the metallic holographic metasurface may have an active control in which the circuits are partially below the holographic surface.

FIG. 1B is a cross-sectional view of a one-dimensional metallic holographic metasurface device in accordance with embodiments of the disclosure. As shown in FIG. 1B, metallic holographic metasurface includes a plurality of columns or an array of metallic holographic elements 106 arranged linearly on a wafer. Each metallic holographic elements 106 (e.g., metallic resonators or metallic antenna elements) includes a pair of metal pillars 110A and 110B and an electrically tunable material 112 between the metal pillars. The metal pillars are deposited over a reflective backplane structure 104. In some embodiments, the backplane structure 104 may include one of a full backplane, a partial backplane, a notch design, a Bragg reflector, or another reflector layer as described in the patent applications incorporated herein by reference.

The grazing incidence of the incident wave, such as a laser input, excites resonances in the gaps between the metal pillars with a relatively high Q factor, enabling dynamic modulation of the phase. Additionally, the metal pillars are deposited over a backplane structure, which makes the structure operate as a reflectarray and thus is possible to integrate with control electronics. The resonator includes two metal pillars that are separated by an electrically tunable material having a tunable refractive index. The resonator produces a holographic output, as shown in FIG. 1B.

The reflection phase of the metal pillars is sensitive to the refractive index of the core material, with phase modulation of nearly 2π possible with an index modulation of Δn/n of about 7%. The high sensitivity to the refractive index of the core material is enabled by the high Q of the resonance, for example, a Q of 20. The high sensitivity of the reflection phase to the refractive index of the core enables the integration of refractive index tunable core material into the gaps between the metal elements to create dynamic metasurfaces.

Since the refractive index modulation range of the tunable dielectric materials may be small, one challenge for designing an array of tunable radiating or scattering elements is to create a high Q factor, low-loss, subwavelength resonators. The Q factor is a dimensionless parameter that characterizes a resonator's bandwidth relative to its center frequency. A high Q factor indicates a lower rate of energy loss relative to the stored energy of the resonator. Resonators with high Q factors have low damping.

The backplane structure 104 is deposited over a base 108 for supporting the metal pillars or rails. In some embodiments, the base 108 may include a wafer substrate, which may be a crystalline silicon wafer, among others. In some embodiments, the base 108 may include a wafer substrate and also a plurality of layers for wires.

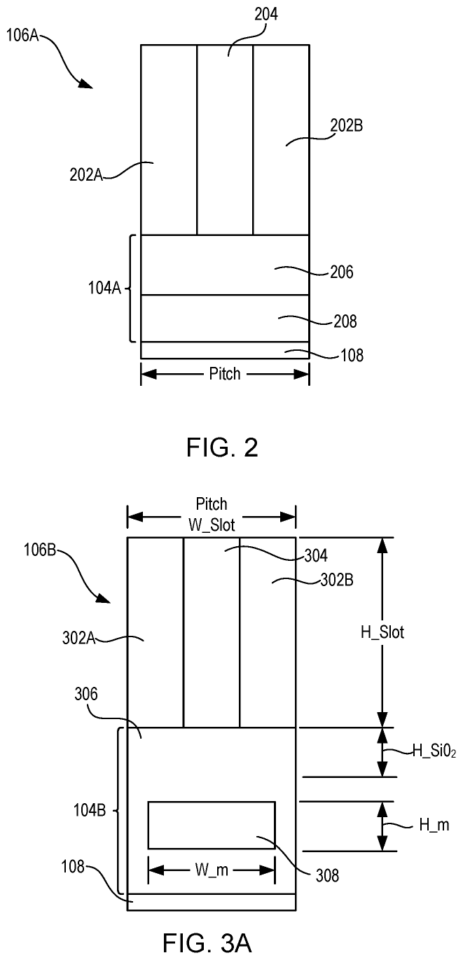

FIG. 2 shows a cross-sectional view of one of the sub-wavelength holographic element 106A having a resonator including a pair of metal pillars 202 and a full backplane structure in the array of FIG. 1B in accordance with embodiments of the disclosure. The backplane structure 104 reflects optical waves. A control voltage is applied across the metal pillars 202 to create a static electric field across the holographic element 106A. Both the electric field and magnetic field are well confined to the electrically tunable material 204 in the nano-gap between the two metal pillars 202A and 202B.

As depicted, a metallic holographic element 106A, e.g., a sub-wavelength metallic holographic element, includes a resonator having an electrically-tunable material or refractive index tunable material 204 between two metal pillars 202, over a backplane structure 104A, which is placed between the base 108 and metal pillars 202A-B. The full backplane structure 104A may include a dielectric spacer layer 206 over a metal layer 208, as shown in FIG. 2. The dielectric spacer layer 206 may include at least one thin chemically resistant layer and a relatively thick dielectric layer.

Both the electric field and magnetic field are well confined to the electrically tunable material 204 in the nano-gap between the two metal pillars 202A-202B. The electric field and magnetic field are mostly confined between both the top end and the bottom end of the resonator.

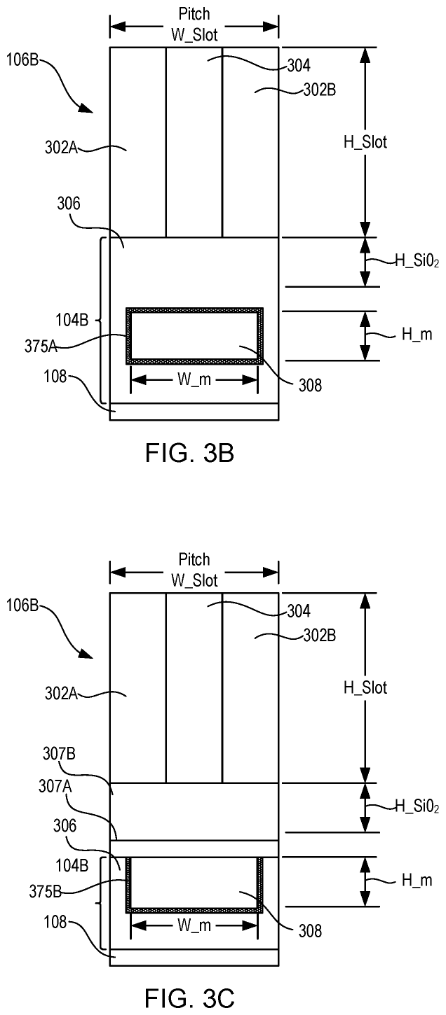

FIG. 3A shows a cross-sectional view of one of the subwavelength holographic element 106B having a resonator including a pair of metal pillars 302A and 302B and a partial backplane structure in the array of FIG. 1B in accordance with embodiments of the disclosure. As depicted, a metallic holographic element 106B, e.g., a sub-wavelength metallic holographic element, includes a resonator having a refractive index tunable material 304 between two metal pillars 302A and 302B, over a backplane structure 104B, which is placed between the base 108 and metal pillars 302A-B. The partial backplane structure 104B may include a metal patch 308 embedded in a dielectric layer 306. The metal patch 308 may be in a rectangular shape having a height labeled as H_m and a width labeled as W_m. The metal patch 308 is located under the electrically tunable material 304. The width of the metal patch 308 may vary from zero to nearly the pitch. When the width of the metal patch equals the pitch, the partial backplane structure becomes a full backplane structure.

When the metal patch is formed of copper, the width of the copper patch may be designed by considering the impact of the width on both manufacturing and optical performance. It may be easier to fabricate the copper patch with a reduced width. However, the optical performance may improve as the width of the copper patch increases (e.g., higher reflectivity). Again, both the electric field and magnetic field are well confined to the electrically tunable material 304 in the nano-gap between the two metal pillars 302A-B. Both the electric field and magnetic field are mostly confined between both the top end and the bottom end of the resonator.

FIG. 3B shows a cross-sectional view of the subwavelength holographic element of FIG. 3A, with a dielectric barrier layer 375A around the partial backplane structure (e.g., the metal patch 308), in accordance with embodiments of the disclosure. As illustrated, the dielectric barrier layer 375A operates to prevent corrosion of the metal patch 308 and/or diffusion of copper or other metals from the metal patch 308 into the dielectric substrate portion of the backplane structure 104B. A dielectric barrier layer 375A is optically transparent or otherwise has low optical absorptive properties. Examples of suitable properties to use for the dielectric barrier layer 375A include SiN, SiC, SiCN, AL₂O₃, HfO₂, and/or SiO₂.

FIG. 3C shows a cross-sectional view of the subwavelength holographic element of FIG. 3A, with a dielectric barrier layer 375B around three sides of a partial backplane structure (e.g., the metal patch 308), in accordance with embodiments of the disclosure. The dielectric barrier layer 375B operates to prevent corrosion of the metal patch 308 and/or diffusion of copper or other metals from the metal patch 308 into the dielectric substrate portion of the backplane structure 104B. Dielectric spacer layers 307A and 307B are positioned on top of the metal patch 308 and separate the metal patch 308 (e.g., the lower metal layer) from the upper metal layers (e.g., the two metal pillars 302A and 302B). Dielectric spacer layer 307A may be selected as a material to avoid diffusion of copper or other metals from the metal patch 308. The dielectric barrier layer 375B is optically transparent or otherwise has low optical absorptive properties, such as SiN, SiC, SiCN, AL₂O₃, HfO₂, and/or SiO₂.

In earlier developments, a Ta or TaN barrier layer was used in the lower metal layer. It was not intuitive that the absorptive properties of Ta or TaN would have a significant impact on the reflectivity of the lower metal layer, especially in embodiment like the one shown in FIG. 3C in which only the sidewalls and bottom wall are coated with the barrier layer. Contrary to expectations, using a dielectric barrier layer 375B with low optical absorptive properties on the sidewalls and bottom wall of the metal patch 308 increases the reflectivity of the lower metal layer. In fact, it was not intuitive that any benefit would be gained by using a dielectric barrier layer in the lower metal layer, despite the use of dielectric coatings on the sidewalls and top walls of upper metal layers.

The specific dimensions may be adjusted based on the specific operational wavelengths, desired tunability, and other operational characteristics and properties. In an example embodiment, the H_Slot may range from 300 to 700 nanometers, the W_Slot may range from 50 nanometers to 300 nanometers, the pitch may range from 200 nanometers to 700 nanometers, and the other dimensions and spacings may be adjusted accordingly, ranging from 50 nanometers to less than 1000 nanometers.

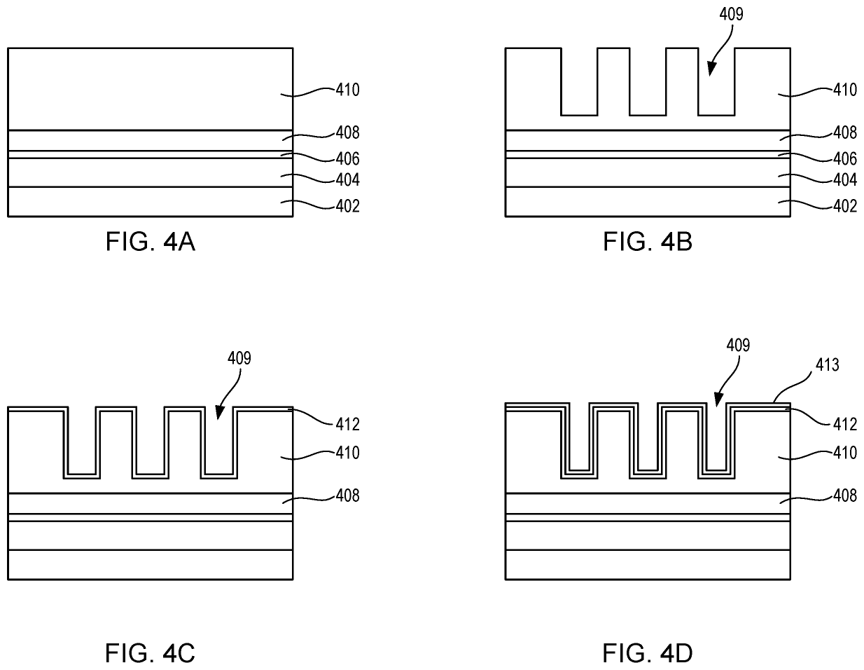

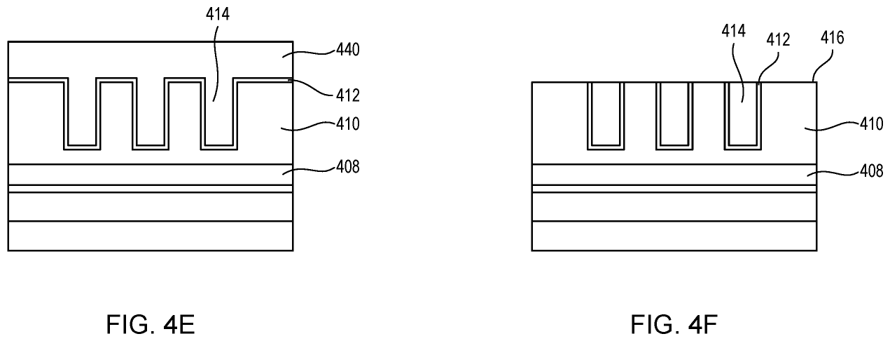

FIGS. 4A-4F illustrate steps for forming a metallic optical metasurface using the damascene process. The metallic optical metasurface includes a partial backplane structure as a reflector, as shown in FIGS. 3A, 3B, and 3C. The illustrated method can be used to fabricate the partial backplane structure with copper patches or patches of another metal.

FIG. 4A shows a cross-sectional view of the deposition of a plurality of dielectric layers over a wafer substrate in accordance with embodiments of the disclosure. A stack of dielectric layers 404, 406, 408, and 410 are deposited over a wafer substrate 402. The dielectric layers may include a dielectric material, such as silicon nitride (SiN), silicon nitride carbide (SiCN), silicon carbide (SiC), aluminum oxide (Al203), hafnium (IV) oxide (HfD2), silicon oxide (Si02), among others. The deposition technique may include physical vapor deposition (PVD), chemical vapor deposition (CVD), or plasma-enhanced chemical vapor deposition (PECVD), among others.

FIGS. 4B-4F show the steps for forming the partial backplane structure as a plurality of copper patches. FIG. 4B shows a cross-sectional view of etching the top dielectric layer of FIG. 4A to form trenches in accordance with embodiments of the disclosure. As shown in FIG. 4B, trenches 409 are formed in the top dielectric layer 410 by dry etch or plasma etch. The dry etch or plasma etch can etch in a vertical direction such that vertical trenches can be formed in the dielectric layers.

FIG. 4C shows a cross-sectional view of depositing a dielectric barrier layer 412 within the trenches 409 in accordance with embodiments of the disclosure.

FIG. 4D shows a copper seed layer 413 deposited within the trenches 409 over the dielectric barrier layer 412 in accordance with embodiments of the disclosure.

FIG. 4E illustrates a copper layer 440 deposited to fill the remaining volume in each of the trenches in accordance with embodiments of the disclosure. As illustrated, the copper layer 440 is protected via the dielectric barrier layer 412, such as SiN or another optically transparent dielectric. Ta and TaN, which might traditionally be used as the barrier layer, are avoided because they absorb optical radiation and reduce the optical reflectivity or reflectance of the partial backplane reflective structure.

In various embodiments, the copper layer 440 may be electroplated into the trenches coated with the dielectric barrier layer 412. The electroplating deposition may be a two-step process. The seed layer 413 (FIG. 4D) may be first deposited using the physical vapor deposition (PVD), and then the copper layer 440 may be electroplated over the seed layer 413 (e.g., via an electrochemical plating or ECP process).

FIG. 4F shows a cross-sectional view of chemical mechanical planarization (CMP) of the copper layer 440 of FIG. 4D to expose the upper surface 416 of the top dielectric layer 410 in accordance with the embodiments of the disclosure. Copper patches 414 are formed via the planarization of the copper layer 440. The copper patches 414 are embedded within the top dielectric layer 610, which is protected from diffusion via the optically transparent dielectric barrier layer 412. The term “lower copper layer” or “optically reflective metallic layer” may be used to describe the stack of dielectric layers 408, the top dielectric layer 410, the dielectric barrier layer 412, and the copper patches 414. The copper patches 414 are illustrated as having heights greater than their widths; however, it is understood that the copper patches 414 may be thinner with heights that are less than their widths.

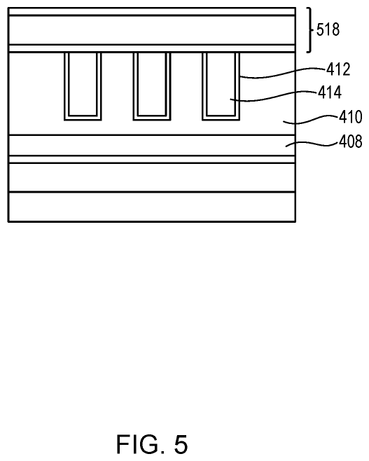

FIG. 5 shows a cross-sectional view of depositing a dielectric spacer 518 over the optically reflective metallic layer, which includes the copper patches 414 and the top dielectric layer 410 in accordance with embodiments of the disclosure. Again, the optically transparent dielectric barrier layer 412 prevents corrosion of the copper patches 414 and diffusion of the copper into the top dielectric layer 410. The dielectric spacer 518 is deposited over the planarized copper patches 414 and the dielectric layer 410. The dielectric spacer 518 may include a plurality of dielectric layers. As an example, the dielectric spacer 518 may include a top nitride layer, a bottom nitride layer, and an oxide layer between the top nitride layer and the bottom nitride layer. The dielectric spacer 518 may include a dielectric material, such as SiN, SiCN, SiC, Al₂O₃, HfO₂, SiO₂, among others. The deposition technique may include PVD, CVD, or PECVD, among others. It will be appreciated by those skilled in the art that the dielectric spacer 518 may vary in materials and thicknesses.

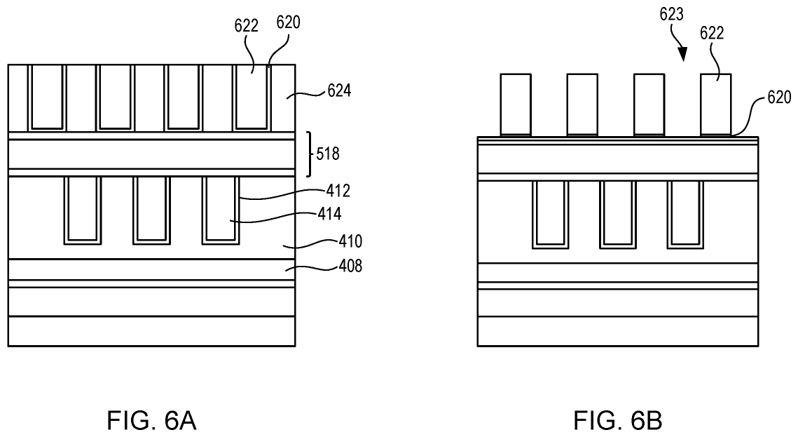

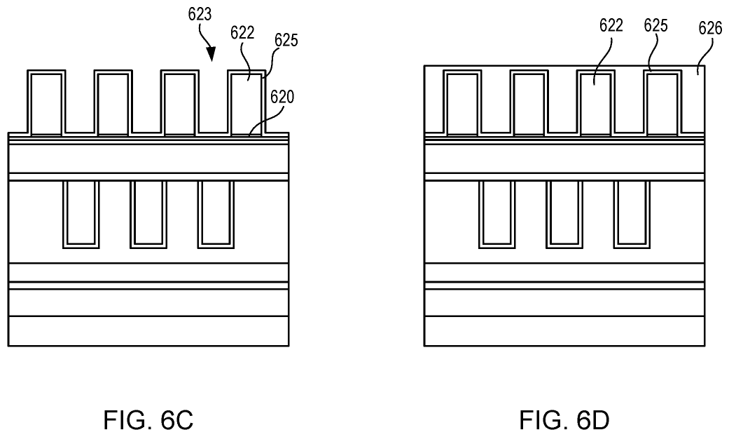

FIG. 6A shows a cross-sectional view of patterning the upper copper layer with the array of holographic elements (e.g., metal pillars or rails) over the dielectric spacer 518 of FIG. 5 using a damascene process in accordance with embodiments of the disclosure. As shown, copper pillars 622 or another conductive metal are formed with nano-gaps in between. A conductive barrier layer 620 covers the sidewalls and the bottom of the copper pillars 622. A dielectric layer 624 (e.g., a dielectric etch layer) fills the space in the nano-gaps between the copper pillars. The conductive barrier layer 620 may be, for example, tantalum (Ta), tantalum nitride (TaN), and titanium nitride (TiN), which prevent metallic diffusion and/or corrosion.

In some embodiments, the damascene process may be a dual-damascene process, which may involve making the electrical via connections between elements in copper pillars 622 and copper patches 414. If a dielectric liner is used instead of the conductive barrier layer 620, these connections cannot be directly made but may be made using thru bores or routing to the top or sides of the copper pillars 622 (or copper rails) in another layer in the IC region.

The conductive barrier layer 620 may be deposited over the trenches, as shown in FIG. 6A, followed by the deposition of the copper layer over the trenches by electroplating and CMP to form copper pillars 622, similar to the process illustrated and described in conjunction with forming the copper patches 414 in FIGS. 4A-4F.

In some embodiments, the vias may not be present in the holographic surface of the metallic optical metasurface, such as shown in FIG. 1A. In alternative embodiments, the vias may be present in an active metallic optical meta-surface (not shown) or in the interconnect region 103 of the metallic optical metasurface. The vias and the trenches are formed using the dual-damascene process. The copper is deposited in the vias and trenches simultaneously in a single deposition operation.

FIG. 6B shows a cross-sectional view of chemically etching the top dielectric layer to form nano-gaps between copper pillars in accordance with embodiments of the disclosure. As shown, the dielectric layer 624 (shown in FIG. 6A) between the copper pillars 622 (within the previously formed trenches) is removed by chemical etching using an etchant, such as buffered oxide etchant (BOE). Chemical etching can etch in all directions, unlike plasma etching. The etchant may etch one dielectric material, such as oxide, but may not etch another neighboring dielectric material, such as nitride.

Also, as shown in FIG. 6B, the etchant removes the conductive barrier layer 620 on the vertical side walls of the copper pillars 622, while the bottom conductive barrier layer 620 remains between the copper pillars 622 and the dielectric spacer 518 underneath the copper pillars 622.

FIG. 6C shows a cross-sectional view of applying a dielectric coating layer 625 to the exposed copper pillars 622 to form protected metal pillars, in accordance with various embodiments of the disclosure. The dielectric coating layer 625 is deposited over the top and sides of the planarized copper pillars 622. The dielectric coating layer 625 is also deposited over the exposed top portion of the dielectric spacer 518 between the copper pillars 622.

The dielectric coating layer 625 may be applied by using atomic layer deposition (ALD) or plasma-enhanced chemical vapor deposition (PECVD). The dielectric coating layer 625 is optically transparent and may include a dielectric material, such as SiN, SiCN, SiC, Al203, HfD2, Si02, and/or other optically transparent materials that are barriers to copper diffusion. The dielectric coating layer 625 may be applied very quickly and/or within a vacuum chamber to minimize oxidation of the copper.

FIG. 6D shows a cross-sectional view of an electrically tunable material 626 disposed over the copper pillars 622 and filling the nano-gaps between copper pillars of FIG. 6C in accordance with embodiments of the disclosure. As shown, the electrically tunable material 626 fills the nano-gap 623 between the copper pillars 622. In this embodiment, the electrically tunable material 626 covers the top of the dielectric coating layer 625.

In an alternative embodiment, the electrically tunable material 626 may not cover the top of the dielectric coating layer 625. The electrically tunable material may include liquid crystals. The electrically tunable material may be spin coated into the nano-gap. In various embodiments, the electrically tunable material may be encapsulated with an optically transparent material, such as glass, sapphire, and/or polymers. The polymers may include, for example, poly(methyl methacrylate) (PMMA) or polycarbonate (PC), or the like.

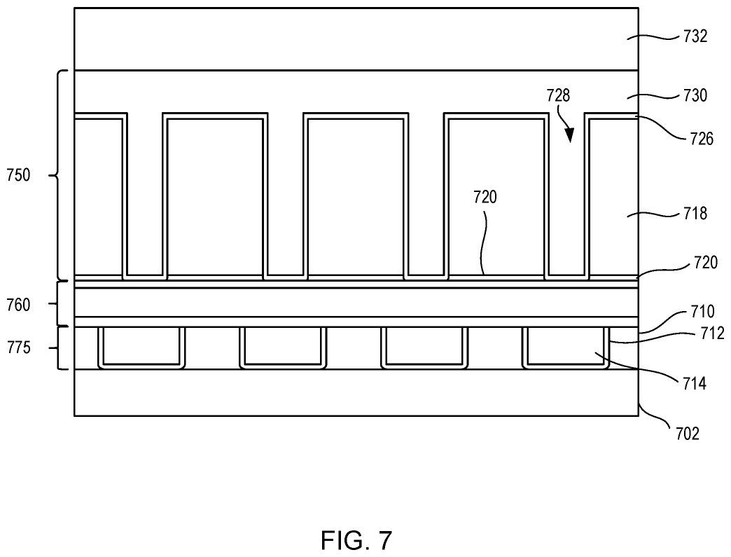

FIG. 7 shows a cross-sectional view of a metasurface with patterned copper elements (e.g., copper pillars, copper rails, or alternative metal pillars or metal rails) and copper patches, according to various embodiments of the disclosure. As illustrated, a lower copper layer 775 forms an optically reflective metallic layer that includes reflective metal patches 714 (e.g., copper) positioned within trenches in a dielectric substrate 710. The lower copper layer 775 includes a dielectric barrier layer 712 between the reflective metal patches 714 and the dielectric substrate 710. The dielectric barrier layer 712 is optically transparent and prevents diffusion of the metal in the reflective metal patches 714 (e.g., copper) into the dielectric substrate 710. The lower copper layer 775 may be formed on a supporting structure or substrate, such as a silicon substrate 702 or silicon wafer.

A dielectric spacer layer 760, such as an optically transparent dielectric spacer layer comprising one or more dielectric layers, is deposited on the optically reflective metallic layer to separate the lower copper layer 775 from the upper copper layer 750. The upper copper layer 750 includes an array of metal holographic elements, as described herein. The upper copper layer 750 includes an array of metal elements 718 (e.g., copper rails or copper pillars) extending from the dielectric spacer layer 760. The metal elements 718 are spaced from one another by less than a wavelength of an operational bandwidth to form subwavelength gaps between adjacent metal elements. The upper copper layer 750 includes a dielectric coating 726 on the top wall and sidewalls of each metal element 718 and a conductive barrier material 720 positioned between a base wall of each metal element 718 and the dielectric spacer layer 760. The upper copper layer 750 includes a tunable dielectric material 730 that has a tunable refractive index positioned within the gaps between adjacent metal elements 718.

In the illustrated embodiment, the electrically tunable material 730 fills the gaps or nano-gaps 728 and also covers the top of the metal elements 718. An optically transparent layer 732 is disposed over the electrically tunable material 730. The optically transparent layer 732 may include a glass, polymer, sapphire, or other material. For example, a solid piece of glass or glass lid can cover and seal the electrically tunable material 730 in place.

In some alternative embodiments, the electrically tunable material 730 only fills the nano-gaps 728 between the metal elements 718 but is not present over the top of the metal elements 718. In such embodiments, the optically transparent layer 732 may be positioned directly on the coated copper pillars and the electrically tunable material.

This disclosure has been made with reference to various exemplary embodiments, including the best mode. However, those skilled in the art will recognize that changes and modifications may be made to the exemplary embodiments without departing from the scope of the present disclosure. While the principles of this disclosure have been shown in various embodiments, many modifications of structure, arrangements, proportions, elements, materials, and components may be adapted for a specific environment and/or operating requirements without departing from the principles and scope of this disclosure. These and other changes or modifications are intended to be included within the scope of the present disclosure.

This disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, required, or essential feature or element. This disclosure should, therefore, be understood to encompass at least the following claims and all possible permutations thereof.

What is claimed:

1. A method for fabricating an optical metasurface, comprising:
forming a reflective backplane structure to include:
a lower copper layer deposited within a dielectric substrate, and
a lower dielectric barrier layer between the lower copper layer and the dielectric substrate;
forming an optically transparent dielectric spacer layer over the reflective backplane structure;
forming an upper copper layer with an upper barrier layer over the dielectric spacer layer by a damascene process, wherein the upper copper layer comprises a plurality of nano-gaps vertically extending from the dielectric spacer layer, wherein the plurality of nano-gaps is filled with a dielectric fill material, wherein the upper barrier layer is between the upper copper layer and the dielectric spacer layer, and also between the upper copper layer and the dielectric fill material;
removing the dielectric fill material and a portion of the upper barrier layer to expose the portions in the nano-gaps of the upper copper layer;
depositing a dielectric coating layer over a top portion and exposed side portions of the upper copper layer to form a protected upper copper layer; and
filling the nano-gaps with an electrically tunable dielectric material that has an electrically tunable refractive index.

2. The method of claim 1, wherein the dielectric barrier layer operates to prevent copper diffusion into the dielectric substrate.

3. The method of claim 1, wherein the lower dielectric barrier layer comprises one or more of SiN, SiC, SiCN, AL₂O₃, HfO₂, and SiO₂.

4. The method of claim 1, wherein the dielectric coating layer comprises one or more of SiN, SiC, SiCN, AL₂O₃, HfO₂, and SiO₂.

5. The method of claim 1, further comprising:
prior to filling the nano-gaps with the electrically tunable dielectric material, depositing an optically reflective metal coating layer over the dielectric coating layer.

6. The method of claim 5, wherein the optically reflective metal coating layer comprises silver.

7. The method of claim 1, wherein the dielectric spacer layer comprises a plurality of optically transparent dielectric layers.

8. The method of claim 1, wherein the dielectric spacer layer comprises a low-k dielectric layer.

9. The method of claim 1, wherein the upper barrier layer is a dielectric barrier layer.

10. The method of claim 1, wherein the upper barrier layer is a conductive barrier layer.

11. The method of claim 10, wherein the upper barrier layer comprises one or more of tantalum (Ta), tantalum nitride (TaN), and titanium nitride (TiN).

12. The method of claim 1, wherein the tunable dielectric material comprises one or more of liquid crystal, an electro-optic polymer, a chalcogenide glass, and a semiconductor material.

13. The method of claim 1, further comprising:
encapsulating the tunable dielectric material with one or more of glass, a polymer, and sapphire.

14. The method of claim 1, wherein the upper copper layer comprises a plurality of copper pillars vertically extending from the dielectric spacer layer.

15. The method of claim 14, wherein the plurality of copper pillars comprises a two-dimensional array of copper pillars.

16. The method of claim 14, wherein the plurality of copper pillars comprises a one-dimensional array of elongated copper rails.

17. The method of claim 14, wherein the lower copper layer comprises copper patches positioned under the nano-gaps between adjacent copper pillars of the upper copper layer.

18. The method of claim 17, wherein the copper patches have a width corresponding to a pitch of the adjacent copper pillars of the upper copper layer.

19. A tunable optical device, comprising:
an optically reflective metallic layer comprising reflective metal patches positioned within trenches in a dielectric substrate;
a dielectric barrier layer between the reflective metal patches and the dielectric substrate, wherein the dielectric barrier layer is optically transparent and prevents diffusion of the reflective metal into the dielectric substrate;
an optically transparent dielectric spacer layer deposited on the optically reflective metallic layer;
an array of metal elements extending from the dielectric spacer layer and spaced from one another by less than a wavelength of an operational bandwidth to form subwavelength gaps between adjacent metal elements;
a dielectric coating on a top wall and sidewalls of each metal element;
a conductive barrier material positioned between a base wall of each metal element and the dielectric spacer layer; and
a tunable dielectric material that has a tunable refractive index is positioned within the gaps between adjacent metal elements.

20. The device of claim 19, wherein the tunable dielectric material comprises one or more of: liquid crystal, an electro-optic polymer, a chalcogenide glass, and a semiconductor material.

21. The device of claim 19, wherein each metal element comprises copper.

22. The device of claim 19, wherein the conductive barrier material comprises one of tantalum (Ta), tantalum nitride (TaN), and titanium nitride (TiN).

23. The device of claim 19, wherein the dielectric coating comprises silicon nitride (SiN).

24. The device of claim 19, wherein a width of each metal element is less than a smallest wavelength of the operational bandwidth, and wherein each metal element extends from the dielectric spacer layer to a height less than the smallest wavelength of the operational bandwidth.

25. The device of claim 19, wherein the array of metal elements comprises a two-dimensional array of metal antenna resonator elements having subwavelength widths, lengths, and heights.

26. The device of claim 19, wherein the array of metal elements comprises a one-dimensional array of elongated metal rails extending from the dielectric spacer layer parallel to one another and spaced from one another such that the gaps form channels between adjacent elongated metal rails.

27. A method for fabricating an optical metasurface, comprising:
forming an optically reflective metallic layer by:
etching a first dielectric layer to form a first plurality of trenches in the dielectric layer,
depositing a dielectric barrier layer within the first plurality of trenches, wherein the dielectric barrier layer operates to prevent metallic diffusion or corrosion, and
depositing a reflective metal on top of the dielectric barrier layer within the first plurality of trenches to fill each of the first plurality of trenches;
depositing an optically transparent dielectric spacer layer over the optically reflective metallic layer;
depositing a dielectric etch layer over the dielectric spacer layer; and
forming an array of metallic holographic elements by:
etching the dielectric etch layer to form a second plurality of trenches in the dielectric etch layer,
depositing a conductive barrier layer within the second plurality of trenches, wherein the conductive barrier layer operates to prevent metallic diffusion or corrosion,
depositing a conductive metal on top of the conductive barrier layer within the second plurality of trenches to fill each of the second plurality of trenches,
removing the dielectric etch layer and the conductive barrier layer between adjacent trenches in the second plurality of trenches to form a plurality of nano-gaps between exposed metal pillars,
depositing a dielectric coating layer over a top portion and exposed side portions of the exposed metal pillars to form protected metal pillars, and
filling the nano-gaps with an electrically tunable dielectric material that has an electrically tunable refractive index.

28. The method of claim 27, wherein the dielectric barrier layer is optically transparent.

29. The method of claim 27, wherein the dielectric barrier layer is optically reflective.

30. The method of claim 27, wherein the reflective metal comprises copper.

31. The method of claim 27, wherein the conductive metal comprises copper.

32. The method of claim 27, wherein the conductive metal comprises copper and wherein depositing the copper comprises:
depositing a copper seed layer on at least a base wall and sidewalls of each of the second plurality of trenches, and
depositing copper to fill any remaining volume in each of the second plurality of trenches using an electrochemical plating (ECP) process.

33. The method of claim 27, wherein the conductive barrier layer comprises one of tantalum (Ta), tantalum nitride (TaN), and titanium nitride (TiN).
